(19) United States
(12) Patent Application Publication
(10) Pub. No.: US 2019/0286785 A1
(43) Pub. Date: Sep. 19, 2019

(54) DESIGN METHOD OF SEMICONDUCTOR INTEGRATED CIRCUIT LAYOUT

(71) Applicant: SAMSUNG ELECTRONICS CO., LTD., Suwon-si (KR)

(72) Inventors: Sangjun PARK, Seoul (KR); Byung-Sung KIM, Suwon-si (KR); Chulhong PARK, Seongnam-si (KR); Chunyub PARK, Saha-gu (KR)

(21) Appl. No.: 16/432,139

(22) Filed: Jun. 5, 2019

Related U.S. Application Data
(63) Continuation of application No. 15/610,751, filed on Jun. 1, 2017.

(30) Foreign Application Priority Data
Nov. 9, 2016 (KR) 10-2016-0149083

(51) Int. Cl. G06F 17/50; H01L 27/02

(52) U.S. Cl. CPC G06F 17/5081; H01L 21/823437; H01L 27/0207

(57) ABSTRACT

A design method of a semiconductor integrated circuit layout and a method of fabricating a semiconductor device, the design method including selecting a first cell layout including at least one first gate pattern; selecting a second cell layout including at least one second gate pattern, the at least one second gate pattern having a gate length that is different from a gate length of the at least one first gate pattern; producing a pattern layout from the first and second cell layouts; and producing a mask layout selectively overlapping the first cell layout on the pattern layout.

### CROSS-REFERENCE TO RELATED APPLICATIONS

This is a continuation application based on pending application Ser. No. 15/610,751, filed Jun. 1, 2017, the entire contents of which is hereby incorporated by reference.

Korean Patent Application No. 10-2016-0149083 filed on Nov. 9, 2016 in the Korean Intellectual Property Office and entitled: “Design Method of Semiconductor Integrated Circuit Layout and Method of Fabricating Semiconductor Device,” is incorporated by reference herein in its entirety.

### BACKGROUND

### 1. Field

Embodiments relate to a design method of semiconductor integrated circuit layout and a method of fabricating a semiconductor device using the same.

### 2. Description of the Related Art

A schematic circuit may be designed by a schematic tool in order to design a semiconductor integrated circuit. The schematic circuit denotes elements included in the semiconductor device and connection relationship between the elements. Each of elements included in the schematic circuit may be designed as patterns such as a conductive pattern, a semiconductor pattern, and an insulation pattern. A layout may then be designed to define vertical and horizontal positions of the patterns, and a photomask may be manufactured based on the layout. Through a photolithography process using the photomask, layers stacked on a semiconductor substrate may be patterned to form a semiconductor integrated circuit with a desired function.

### SUMMARY

The embodiments may be realized by providing a design method of a semiconductor integrated circuit layout, the method including selecting a first cell layout including at least one first gate pattern; selecting a second cell layout including at least one second gate pattern, the at least one second gate pattern having a gate length that is different from a gate length of the at least one first gate pattern; producing a pattern layout from the first and second cell layouts; and producing a mask layout selectively overlapping the first cell layout on the pattern layout.

The embodiments may be realized by providing a method of fabricating a semiconductor device, the method including providing a substrate including a first region and a second region; forming preliminary mask patterns on the first and second regions such that the preliminary mask patterns have the same width with each other; forming a mask pattern on the substrate such that the mask pattern has an opening that exposes one of the first and second regions; forming spacer patterns on sidewalls of the preliminary mask patterns of the first region by using the mask pattern; and forming first gate electrode patterns on the first region and second gate electrode patterns on the second region by using the preliminary mask patterns and the spacer patterns as masks, wherein forming the mask pattern includes providing a pattern layout that includes a first cell layout inclusive of at least one first gate pattern and a second cell layout inclusive of at least one second gate pattern such that the at least one second gate pattern has a gate length different from a gate length of the at least one first gate pattern; producing a mask layout on the pattern layout such that the mask layer selectively overlaps the first cell layout; manufacturing a photomask that includes a pattern corresponding to the mask layout; and transferring the pattern onto the substrate by performing a photolithography process using the photomask.

The embodiments may be realized by providing a method of fabricating a semiconductor device, the method including providing a substrate including a first region and a second region; forming preliminary mask patterns on the first and second regions such that the preliminary mask patterns have the same width with each other; forming a mask pattern on the substrate such that the mask pattern has an opening that exposes one of the first and second regions; forming spacer patterns on sidewalls of the preliminary mask patterns in the first region; forming first gate electrode patterns on the first region by using the preliminary mask patterns and the spacer patterns as masks; and forming second gate electrode patterns on the second region by using the preliminary mask patterns as masks, wherein forming the mask pattern includes providing a pattern layout that includes a first cell layout inclusive of at least one first gate pattern and a second cell layout inclusive of at least one second gate pattern such that the at least one second gate pattern has a gate length different from a gate length of the at least one first gate pattern; producing a mask layout on the pattern layout such that the mask layer selectively overlaps the first cell layout; manufacturing a photomask that includes a pattern corresponding to the mask layout; and transferring the pattern onto the substrate by performing a photolithography process using the photomask.

### BRIEF DESCRIPTION OF THE DRAWINGS

Features will become apparent to those of ordinary skill in the art by describing in detail exemplary embodiments with reference to the attached drawings in which:

FIG. 1 illustrates a flow chart of a design method of semiconductor integrated circuit layout according to exemplary embodiments.

FIGS. 2 to 5 illustrate conceptual diagrams of the steps of FIG. 1.

FIG. 6 illustrates an enlarged view of a portion of FIG. 5.

FIG. 7A illustrates a flow chart of a method of fabricating a semiconductor device according to exemplary embodiments.

FIG. 7B illustrates a flow chart of step S500 of FIG. 7A.

FIGS. 8 to 13 illustrate cross-sectional views of stages in a method of fabricating a semiconductor device according to exemplary embodiments.

FIGS. 14 to 17 illustrate cross-sectional views of stages in a method of fabricating a semiconductor device according to exemplary embodiments.

### DETAILED DESCRIPTION

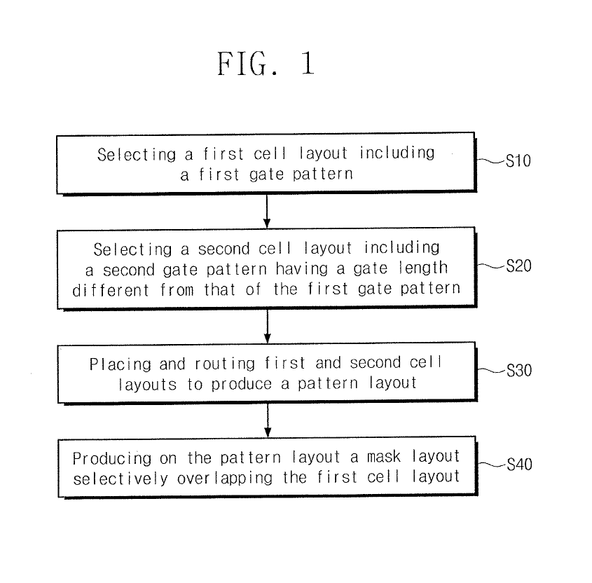

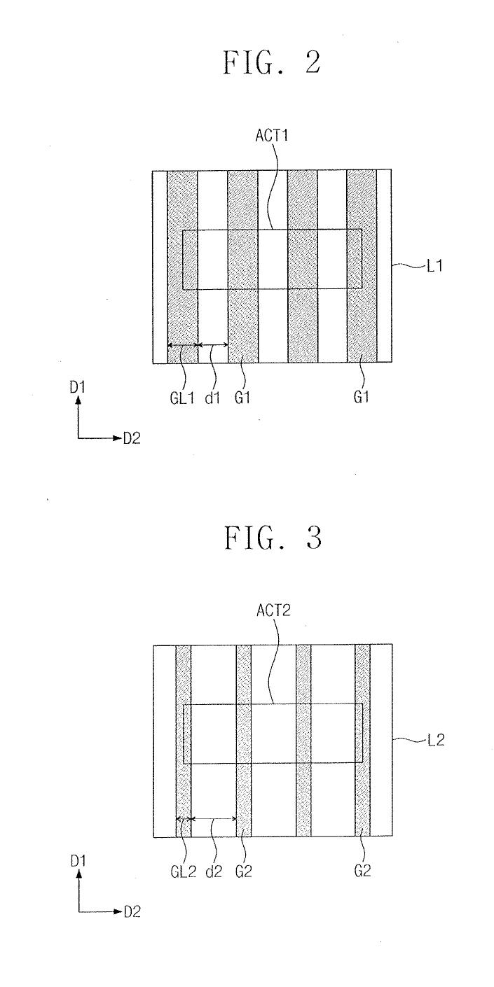

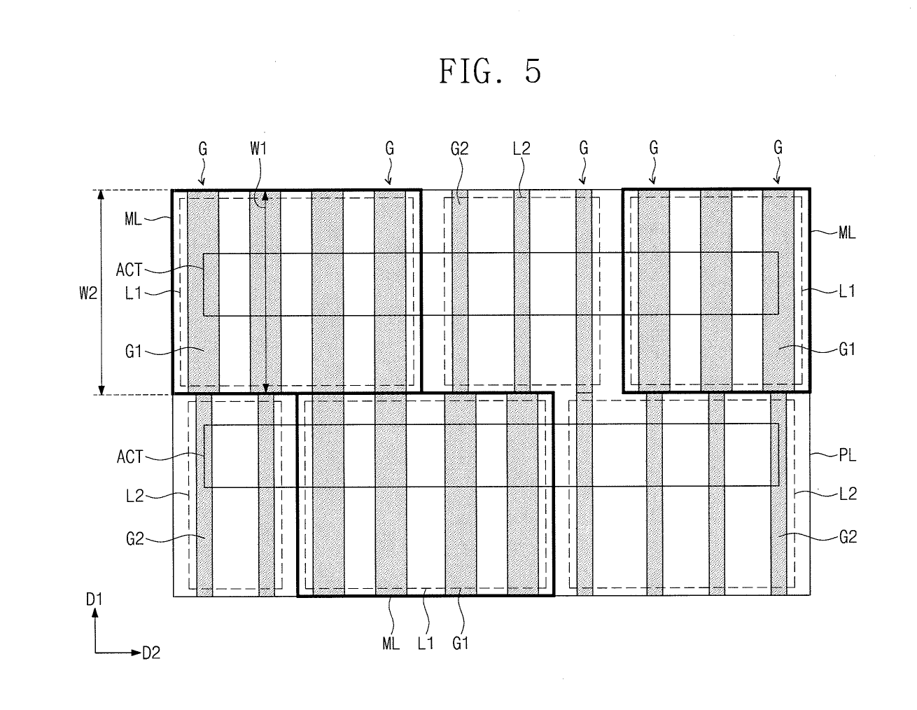

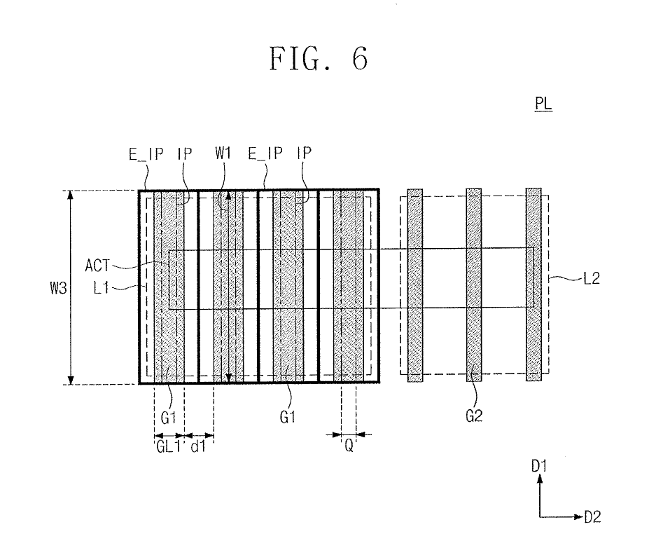

FIG. 1 illustrates a flow chart of a design method of semiconductor integrated circuit layout according to exemplary embodiments. FIGS. 2 to 5 illustrate conceptual diagrams of the steps of FIG. 1. FIG. 6 illustrates an enlarged view of a portion of FIG. 5.

Referring to FIGS. 1 and 2, a first cell layout L1 including a first gate pattern G1 may be selected (S10). The first cell layout L1 may be selected from a cell library including various cell layouts for forming a semiconductor integrated circuit on a semiconductor substrate. The first cell layout L1 may include suitably formatted data (e.g., GDS II) for defining sizes and shapes of patterns that will be formed on the semiconductor substrate. The first cell layout L1 may include patterns for forming a specific transistor on the semiconductor substrate. The first cell layout L1 may include a first active pattern ACT1 and at least one first gate pattern G1 running across the first active pattern ACT1. As viewed in plan, the first gate pattern G1 may extend in a first direction D1 and the first active pattern ACT1 may extend in a second direction D2 crossing the first direction D1. The first gate pattern G1 may have a first gate length GL1. The first gate length GL1 may be a width in the second direction D2 of the first gate pattern G1.

The first cell layout L1 may include a plurality of first gate patterns G1. Each of the first gate patterns G1 may run across the first active pattern ACT1. The plurality of first gate patterns G1 may extend in the first direction D1 and be arranged (e.g., spaced apart) in the second direction D2. Each of the first gate patterns G1 may have a first gate length GL1. The plurality of first gate patterns G1 may be spaced apart from each other at a first distance d1 along the second direction D2. In an implementation, the number of first gate patterns G1 in the first cell layout L1 may be, e.g., four.

Referring to FIGS. 1 and 3, a second cell layout L2 including a second gate pattern G2 may be selected (S20). The second cell layout L2 may be selected from the cell library. The second cell layout L2 may include suitably formatted data (e.g., GDS II) for defining sizes and shapes of patterns that will be formed on the semiconductor substrate. The second cell layout L2 may include patterns for forming a specific transistor on the semiconductor substrate. The second cell layout L2 may include a second active pattern ACT2 and at least one second gate pattern G2 running across the second active pattern ACT2. As viewed in plan, the second gate pattern G2 may extend in the first direction D1 and the second active pattern ACT2 may extend in the second direction D2. The second gate pattern G2 may have a second gate length GL2. The second gate length GL2 may be a width in the second direction D2 of the second gate pattern G2. The second gate length GL2 may be different from the first gate length GL1. For example, the second gate length GL2 may be less than the first gate length GL1.

The second cell layout L2 may include a plurality of second gate patterns G2. Each of the second gate patterns G2 may run across the second active pattern ACT2. The plurality of second gate patterns G2 may extend in the first direction D1 and be arranged (e.g., spaced apart) in the second direction D2. Each of the second gate patterns G2 may have the second gate length GL2. The plurality of second gate patterns G2 may be spaced apart from each other at a second distance d2 along the second direction D2. The second distance d2 may be different from the first distance d1. For example, the second distance d2 may be greater the first distance d1. In an implementation, the number of second gate patterns G2 in the second cell layout L2 may be, e.g., four.

As the first and second cell layouts L1 and L2 respectively include the first and second gate patterns G1 and G2 having different gate lengths from each other, transistors formed by the first and second cell layouts L1 and L2 may have different operating characteristics from each other. In an implementation, the first gate length GL1, the second gate length GL2, the first distance d1, and the second distance d2 may have values different from one another (e.g., may each be different lengths).

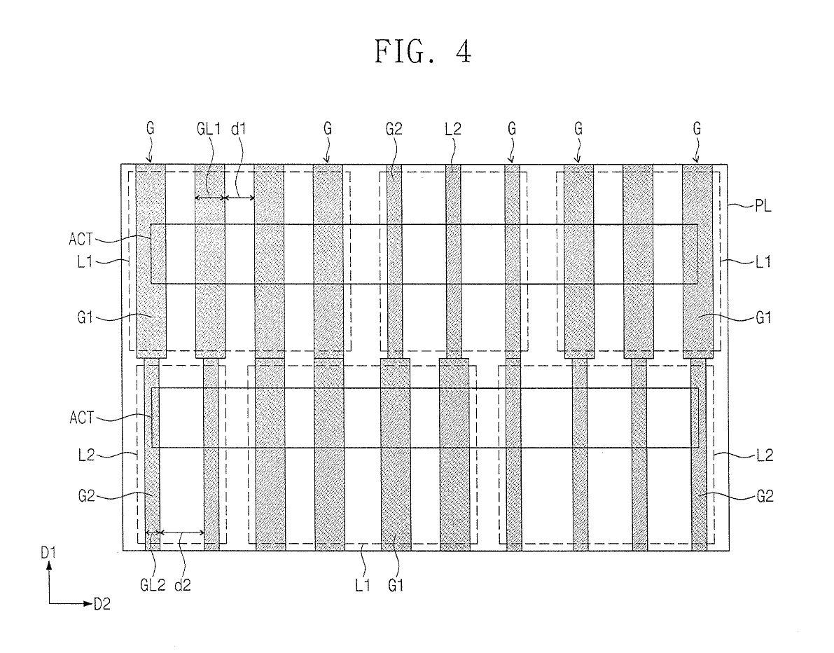

Referring to FIGS. 1 and 4, the first and second cell layouts L1 and L2 may be used to produce a pattern layout PL (S30). The pattern layout PL may include data whose format is the same (e.g., GDS II) as those of the first and second cell layouts L1 and L2. As viewed in plan, the production of the pattern layout PL may include placing and routing the first and second cell layouts L1 and L2 in accordance with a preset design rule. The pattern layout PL may include a plurality of the first cell layouts L1 and a plurality of the second cell layouts L2 that are arranged along the first and second directions D1 and D2.

The pattern layout PL may include an active pattern ACT and at least one gate pattern G running across the active pattern ACT. The gate pattern G may extend in the first direction D1, and the active pattern ACT may extend in the second direction D2. The pattern layout PL may include a plurality of gate patterns G. Each of the gate patterns G may run across the active pattern ACT. The plurality of gate patterns G may extend in the first direction D1 and be arranged (e.g., spaced apart) in the second direction D2. The active pattern ACT may be defined by connection between the first and second active patterns ACT1 and ACT2 of the first and second cell layouts L1 and L2 that are adjacent to each other in the second direction D2. Each of the gate patterns G may include at least one of the first gate pattern G1 and the second gate pattern G2. One or more of the gate patterns G may be defined by connection between neighboring first gate patterns G1, in the first direction D1, of the first gate patterns G1 included in the first cell layouts L1 adjacent to each other in the first direction D1. Another one or more of the gate patterns G may be defined by connection between neighboring second gate patterns G2, in the first direction D1, of the second gate patterns G2 included in the second cell layouts L2 adjacent to each other in the first direction D1. Other one or more of the gate patterns G may be defined by connection between neighboring first and second gate patterns G1 and G2, in the first direction D1, of the first and second gate patterns G1 and G2 included in the first and second cell layouts L1 and L2 adjacent to each other in the first direction D1.

In the pattern layout PL, the first gate patterns G1 neighboring or adjacent to one another in the second direction D2 may be spaced apart from each other at the first distance d1, and the second gate patterns G2 adjacent to one another in the second direction D2 may be spaced apart from each other at the second distance d2. As each of the plurality of gate patterns G includes at least one of the first gate pattern G1 and the second gate pattern G2 having different gate lengths from each other, at least one of transistors formed by the pattern layout PL may have different operating characteristics from other transistors.

Referring to FIGS. 1 and 5, a mask layout ML selectively overlapping the first cell layout L may be provided on the pattern layout PL (S40). The mask layout ML may not overlap the second cell layout L2. For example, the mask layout ML may overlap the first gate pattern G1 of the first cell layout L1 and may not overlap the second gate pattern G2 of the second cell layout L2. The first gate pattern G1 may have a width W1 along the first direction D1. The mask layout ML may have a width W2 along the first direction D1, and the width W2 of the mask layout ML may be substantially the same as the width W1 of the first gate pattern G1. When the first cell layout L1 includes the plurality of first gate patterns G1, the mask layout ML may overlap the plurality of first gate patterns G1 and extend in the second direction D2 to further overlap regions between the plurality of first gate patterns G1. When the second cell layout L2 includes the plurality of second gate patterns G2, the mask layout ML may overlap neither the plurality of second gate patterns G2 nor regions between the plurality of second gate patterns G2.

The pattern layout PL may include the plurality of first cell layouts L1 and the plurality of second cell layouts L2. In this case, a plurality of the mask layouts ML selectively overlapping the plurality of the first cell layouts L1 may be provided on the pattern layout PL. Each of the plurality of the mask layouts ML may overlap a corresponding one of the plurality of the first cell layouts L1.

A Boolean equation may be used to produce the mask layout ML. For example, referring to FIG. 6, the pattern layout PL may be provided thereon with an imaginary pattern IP overlapping the first gate pattern G1 of the first cell layout L1. When the first cell layout L1 includes the plurality of first gate patterns G1, a plurality of imaginary patterns IP may be produced to respectively overlap the plurality of first gate patterns G1. The plurality of imaginary patterns IP may extend in the first direction D1 and be arranged in the second direction D2. Each of the imaginary patterns IP may have a width W3 along the first direction D1, and the width W3 of each of the imaginary patterns IP may be substantially the same as the width W1 of each of the first gate patterns G1. Each of the imaginary patterns IP may extend in the second direction D2 to produce an extended imaginary pattern E_IP. The production of the extended imaginary patterns E_IP may include performing the Boolean equation to extend the plurality of the imaginary patterns IP in the second direction D2. For example, each of the imaginary patterns IP may have a length Q along the second direction D2. The Boolean equation may cause the length Q of each of the plurality of the imaginary patterns IP to change into a sum of the first gate length GL1 of each of the plurality of the first gate patterns G1 and the first distance d1 between the plurality of the first gate patterns GI1 (i.e., Q=Q′, Q′=GL+d1). As such, the plurality of the imaginary patterns IP may extend in the second direction D2. The extended imaginary patterns E_IP may have the width W3 along the first direction D1. The extended imaginary patterns E_IP adjacent to one another in the second direction D2 may overlap each other, and the Boolean equation may cause the neighboring extended imaginary patterns E_IP to merge to define the mask layout ML. The mask layout ML may be employed to manufacture a photomask used in photolithography for fabricating a semiconductor device.

When designing a semiconductor integrated circuit layout, gate patterns may be generally designed to have the same gate length determined by design rules. In this case, in order to obtain diverse operating characteristics of transistor biasing may be performed to minutely adjust the gate length. A gate pattern to be biased may be provided thereon with a biasing marker to indicate a biasing target.

According to a design method of a semiconductor integrated circuit layout in accordance with an embodiment, the first and second gate patterns G1 and G2 may be designed to have a gate length suitable for desired operating characteristics of transistor without providing biasing markers on the first and second gate patterns G1 and G2. For example, the first and second gate patterns GI1 and G2 may be designed to have different gate lengths from each other. In this case, a Boolean equation may be used to easily design the mask layout ML selectively overlapping the first gate pattern G1.

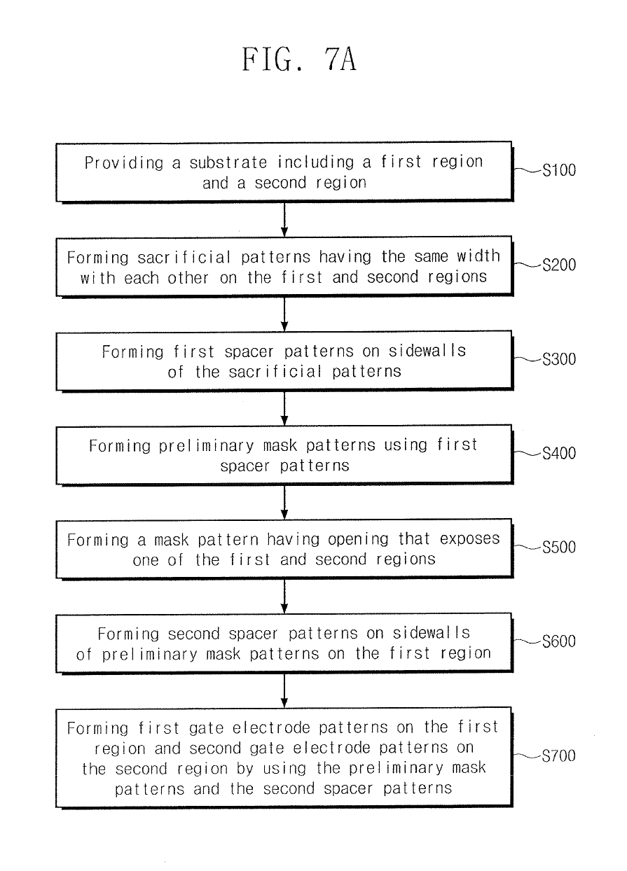

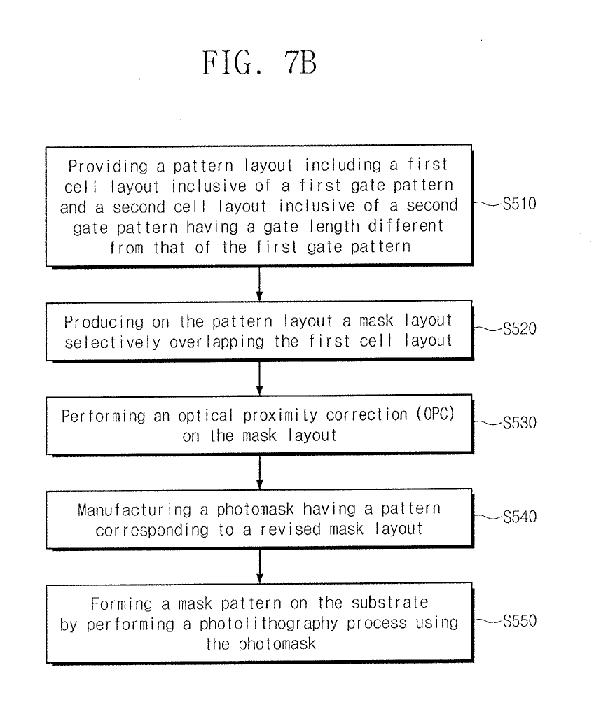

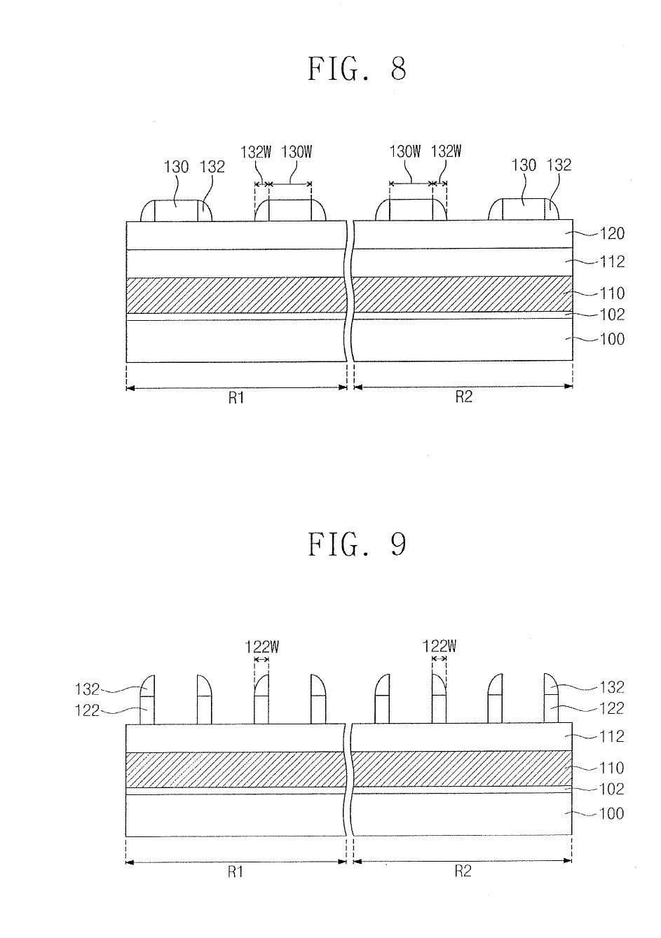

FIG. 7A illustrates a flow chart of a method of fabricating a semiconductor device according to exemplary embodiments. FIG. 7B illustrates a flow chart of a step S500 of FIG. 7A. FIGS. 8 to 13 illustrate cross-sectional views of stages in a method of fabricating a semiconductor device according to exemplary embodiments.

Referring to FIGS. 7A and 8, a substrate 100 may be provided to include a first region R1 and a second region R2 (S100). The substrate 100 may be a semiconductor substrate. The first region R1 may be provided thereon with transistors whose operating characteristics are different from those of transistors provided on the second region R2. A gate dielectric layer 102, a gate electrode layer 110, a gate capping layer 112, and a preliminary mask layer 120 may be sequentially formed on the substrate 100. The gate dielectric layer 102, the gate electrode layer 110, the gate capping layer 112, and the preliminary mask layer 120 may cover the first and second regions R1 and R2. The gate dielectric layer 102 may include, e.g., an oxide. The gate electrode layer 110 may include, e.g., polycrystalline silicon, a metal, and/or a conductive metal nitride. The gate capping layer 112 may include, e.g., an oxide and/or a nitride. The preliminary mask layer 120 may include, e.g., a nitride.

Sacrificial patterns 130 may be formed on the preliminary mask layer 120 (S200). The sacrificial patterns 130 may have a same width 130W with each other on the first and second regions R1 and R2. The sacrificial patterns 130 may include a material having an etch selectivity with respect to the preliminary mask layer 120. For example, the sacrificial patterns 130 may include polycrystalline silicon.

First spacer patterns 132 may be formed on sidewalls of the sacrificial patterns 130 (S300). In an implementation, the first spacer patterns 132 may be formed on opposite sidewalls of each of the sacrificial patterns 130. Forming the first spacer patterns 132 may include forming a first spacer layer on the preliminary mask layer 120 such that the first spacer layer covers the sacrificial patterns 130 and then anisotropically etching the first spacer layer. The first spacer patterns 132 may include a material having an etch selectivity with respect to the sacrificial patterns 130 and the preliminary mask layer 120. For example, the first spacer patterns 132 may include silicon oxide. The first spacer patterns 132 may have a same maximum width 132W with each other on the first and second regions R1 and R2.

Referring to FIGS. 7A and 9, the sacrificial patterns 130 may be removed. The removal of the sacrificial patterns 130 may include, e.g., performing a wet etch process having an etch selectivity to the first spacer patterns 132 and the preliminary mask layer 120. After the sacrificial patterns 130 are removed, the first spacer patterns 132 may be used to form preliminary mask patterns 122 (S400), e.g., the first spacer patterns 132 may be masks for etching of the preliminary mask layer 120. For example, formation of the preliminary mask patterns 122 may include patterning the preliminary mask layer 120 by performing an etch process that uses the first spacer patterns 132 as an etch mask. The preliminary mask patterns 122 may have the same width 122W with each other on the first and second regions R1 and R2. The width 122W of each of the preliminary mask patterns 122 may be substantially the same as the maximum width 132W of each of the first spacer patterns 132.

Referring to FIGS. 7A and 10, a mask pattern 140 may be formed on the substrate 100 (S500). The mask pattern 140 may have an opening 142 that exposes one of the first and second regions R1 and R2. In an implementation, as shown in FIG. 10, the mask pattern 140 may have the opening 142 through which the first region R1 is exposed. The mask pattern 140 may cover the preliminary mask patterns 122 on the second region R2. The opening 142 may expose the preliminary mask patterns 122 on the first region R1. The mask pattern 140 may include a material having an etch selectivity with respect to the preliminary mask patterns 122 and the gate capping layer 112. For example, the mask pattern 140 may include a spin-on-hardmask (SOH) material.

The mask pattern 140 may be formed by using the mask layout ML that is designed by a design method of a semiconductor integrated circuit layout according to exemplary embodiments.

For example, referring to FIG. 7B, the pattern layout PL may be provided to include the first cell layout L1 and the second cell layout L2 as discussed with reference to FIG. 4 (S510). The first cell layout L1 may include the first gate pattern G1 having the first gate length GL1, and the second cell layout L2 may include the second gate pattern G2 having the second gate length GL2. The first gate length GL1 may be different from the second gate length GL2. The first gate pattern G1 may define a planar shape of a first gate electrode pattern to be formed on the first region R1 of the substrate 100, and the second gate pattern G2 may define a planar shape of a second gate electrode pattern to be formed on the second region R2 of the substrate 100.

As discussed with reference to FIG. 5, the pattern layout PL may be provided thereon with the mask layout ML selectively overlapping the first cell layout L1 (S520). The mask layout ML may overlap the first gate pattern G1 of the first cell layout L1 and may not overlap the second gate pattern G2 of the second cell layout L2. When the first cell layout L1 includes the plurality of first gate patterns G1, the mask layout ML may overlap the plurality of first gate patterns G1 and may further overlap regions between the plurality of first gate patterns G1. When the second cell layout L2 includes the plurality of second gate patterns G2, the mask layout ML may overlap neither the plurality of second gate patterns G2 nor regions between the plurality of second gate patterns G2. The mask layout ML may be easily produced by using a Boolean equation as discussed with reference to FIG. 6. In an implementation, the mask layout ML may define a planar shape of the opening 142 exposing the first region R1 of the substrate 100.

An optical proximity correction (OPC) may be performed on the mask layout ML (S530). A photomask may be used to transfer a designed layout onto a semiconductor substrate, and the substrate may be printed with a layout distorted from the designed layout due to interference and/or diffraction of light created when performing a photolithography process using the photomask. The optical proximity correction (OPC) may be performed to help reduce or prevent the layout distortion. According to the optical proximity correction (OPC), the degree of distortion (such as interference and diffraction of light) may be predicted in advance and the designed layout may be revised on the basis of the predicted result. As the optical proximity correction (OPC) is performed on the mask layout ML, a revised mask layout ML may be obtained.

The revised mask layout ML may be used to manufacture the photomask (S540). The photomask may include patterns corresponding to the revised mask layout ML. For example, the photomask may include a transparent segment and an opaque segment. The transparent segment may allow light to pass through, and the opaque segment may not allow light to pass through. The transparent and opaque segments may define the patterns. The manufacturing of the photomask may include providing, on a quartz substrate, a blank mask where a metal layer and a photosensitive layer are formed, transferring the revised mask layout ML onto the photosensitive layer of the blank mask, developing the photosensitive layer to form photosensitive patterns corresponding to the revised mask layout ML, and etching the metal layer (e.g., a chromium layer) of the blank mask by performing an etch process that uses the photosensitive patterns as an etch mask. The etch process may form the transparent segment of the photomask.

The mask pattern 140 may be formed on the substrate 100 by performing a photolithography process that uses the photomask (S550). In an implementation, as shown in FIG. 10, the mask pattern 140 may be formed to have the opening 142 exposing the first region R1, and the opening 142 may be formed to have a planar shape defined by the mask layout ML.

After the mask pattern 140 is formed, a second spacer layer 150 may be formed on the substrate 100. The second spacer layer 150 may cover sidewalls and top surfaces of the preliminary mask patterns 122 on the first region R1, and may further cover a top surface of the mask pattern 140 on the second region R2. The second spacer layer 150 may include a material having an etch selectivity with respect to the gate capping layer 112, the preliminary mask patterns 122, and the mask pattern 140. For example, the second spacer layer 150 may include silicon oxide.

Referring to FIGS. 7A and 11, second spacer patterns 152 may be formed on sidewalls of the preliminary mask patterns 122 on the first region R1 (S600). The formation of the second spacer patterns 152 may include performing an anisotropic etch process on the second spacer layer 150. The etch process may expose the top surfaces of the preliminary mask patterns 122 on the first region R1 and a top surface of the gate capping layer 112 between the preliminary mask patterns 122 on the first region R1. In addition, the etch process may further expose the top surface of the mask pattern 140 (e.g., in the second region R2). The second spacer patterns 152 may have the same maximum width 152W with each other. The presence of the mask pattern 140 may cause the second spacer patterns 152 to locally or selectively form on the first region R1.

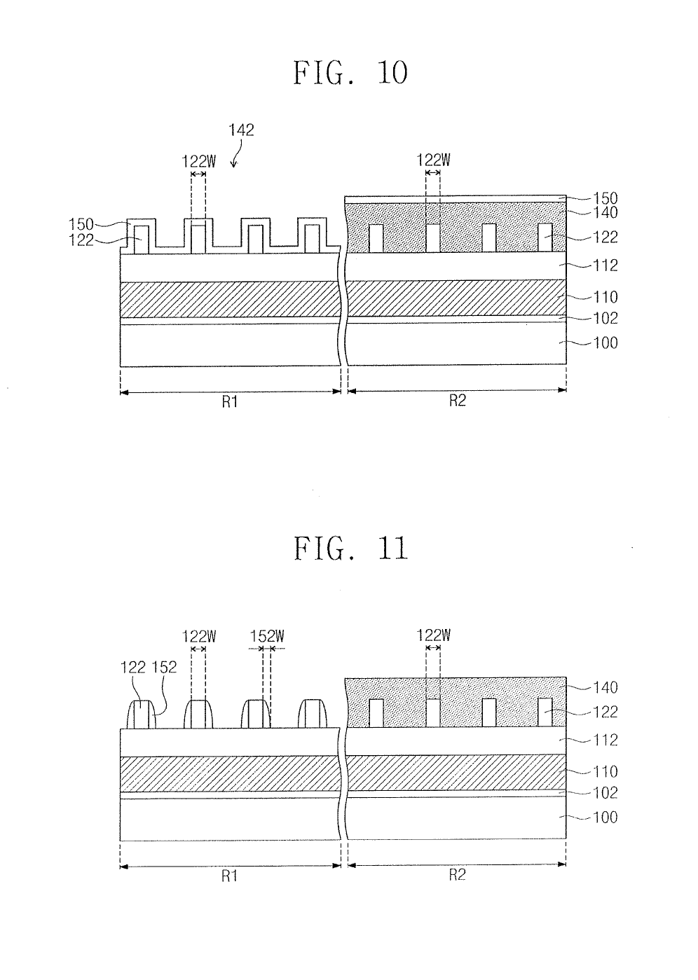

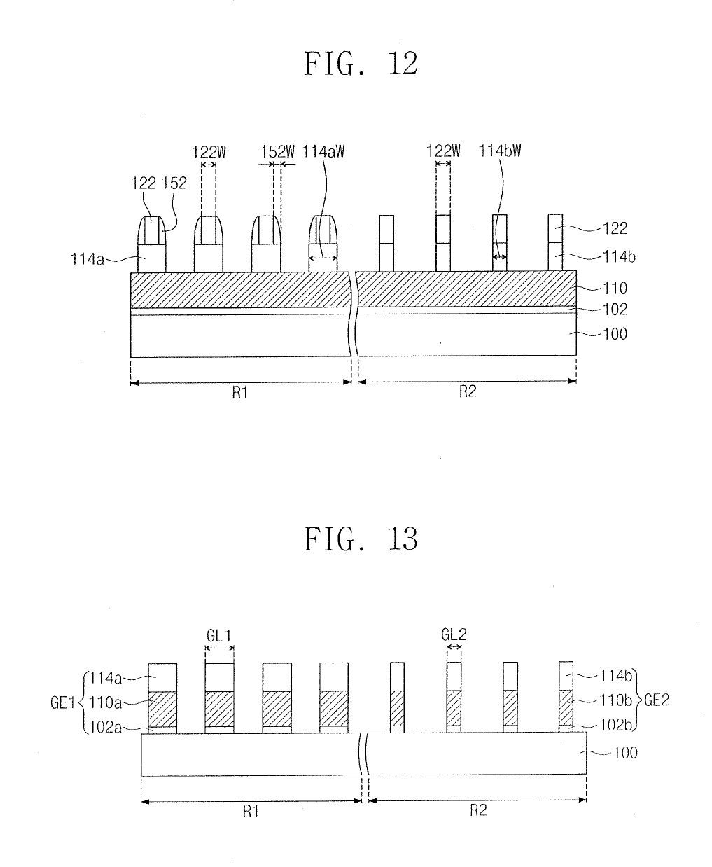

Referring to FIGS. 7A, 12, and 13, the mask pattern 140 may be removed. The mask pattern 140 may be removed by performing, e.g., an ashing and/or strip process. After that, the preliminary mask patterns 122 and the second spacer patterns 152 may be used to form first gate electrode patterns GE1 on the first region R1 and second gate electrode patterns GE2 on the second region R2 (S700). For example, referring to FIG. 12, the gate capping layer 112 may be patterned by an etch process that uses the preliminary mask patterns 122 and the second spacer patterns 152 as an etch mask. Accordingly, first gate capping patterns 114a may be formed on the first region R1 and second gate capping patterns 114b may be formed on the second region R2. The first gate capping patterns 114a may be formed by etching the gate capping layer 112 using the preliminary mask patterns 122 and the second spacer patterns 152 on the first region R1 as an etch mask. Each of the first gate capping patterns 114a may be formed by using its corresponding preliminary mask pattern 122 and a pair of the second spacer patterns 152 on opposite sidewalls thereof as an etch mask when etching the gate capping layer 112. Accordingly, each of the first gate capping patterns 114a may have a width 114aW substantially the same as a sum of the width 122W of the corresponding preliminary mask pattern 122 and twice the width 152W of each of the second spacer patterns 152 (e.g., 114aW=122W+152W×2). The second gate capping patterns 114b may be formed by etching the gate capping layer 112 using the preliminary mask patterns 122 on the second region R2 as an etch mask. Each of the second gate capping patterns 114b may be formed by using its corresponding preliminary mask pattern 122 as an etch mask when etching the gate capping layer 112. Accordingly, each of the second gate capping patterns 114b may have a width 114bW substantially the same as the width 122W of the corresponding preliminary mask pattern 122 (e.g., 114bW=122W). As a result, the first gate capping patterns 114a may be wider than the second capping patterns 114b (e.g., 114aW>114bW). Referring to FIG. 13, the first and second gate capping patterns 114a and 114b may be used as etch masks to pattern the gate electrode layer 110 and the gate dielectric layer 102. Thus, first gate electrodes 110a and first gate dielectric patterns 102a may be formed on the first region R1, and second gate electrodes 110b and second gate dielectric patterns 102b may be formed on the second region R2. Each of the first gate electrode patterns GE1 may include one of the first gate capping patterns 114a, one of the first gate electrodes 110a, and one of the first gate dielectric patterns 102a that are vertically stacked on the substrate 100. Each of the second gate electrode patterns GE2 may include one of the second gate capping patterns 114b, one of the second gate electrodes 110b, and one of the second gate dielectric patterns 102b that are vertically stacked on the substrate 100.

The first gate electrode patterns GE1 may have a first gate length GL1, and the second gate electrode patterns GE2 may have a second gate length GL2. The second gate length GL2 may be different from the first gate length GL. The first gate length GL1 may be substantially the same as the width 114aW of each of the first gate capping patterns 114a, and the second gate length GL2 may be substantially the same as the width 114bW of each of the second gate capping patterns 114b. For example, the second gate length GL2 may be less than the first gate length GL1. As the first gate electrode patterns GE1 are formed to have different gate lengths from those of the second gate electrode patterns GE2, the first region R1 may be provided thereon with transistors whose operating characteristics are different from those of transistors provided on the second region R2.

According to a method of fabricating a semiconductor device in accordance with exemplary embodiments, the second spacer patterns 152 may be locally or selectively formed on the first region R1 using the mask pattern 140 having the opening 142 that exposes the first region R1. In this case, the first and second gate electrodes patterns GE1 and GE2 having a fine pitch may be easily formed to have different gate lengths from each other. The opening 142 of the mask pattern 140 may have a planar shape corresponding to the mask layout ML designed in accordance with a design method of a semiconductor integrated circuit layout according to the embodiments. In a step for designing a semiconductor integrated circuit layout, gate patterns may be designed to have different gate lengths from each other without being provided with a biasing marker, and thus may be employed to easily form the mask layout ML. As such, the first and second gate electrode patterns GE1 and GE2 may be easily formed to have different gate lengths from each other.

FIGS. 14 to 17 illustrate cross-sectional views of stages in a method of fabricating a semiconductor device according to exemplary embodiments. In the embodiment that follows, differences from the method of fabricating a semiconductor device described with reference to FIGS. 7A, 7B, and 8 to 13 may be chiefly discussed herein in the interest of brevity.

First, as discussed with reference to FIGS. 7A, 8, and 9, the substrate 100 may be provided to include the first region R1 and the second region R2 (S100), and then the substrate 100 may be provided thereon with the sacrificial patterns 130 having the same width 130W with each other (S200). The first spacer patterns 132 may be formed on the sidewalls of the sacrificial patterns 130 (S300), and may be used to form the preliminary mask patterns 122 on the substrate 100 (S400). The preliminary mask patterns 122 may be formed to have the same width 122W with each other on the first and second regions R1 and R2.

Referring to FIG. 14, after the preliminary mask patterns 122 are formed, the second spacer layer 150 may be formed on the substrate 100. According to the current embodiment, the second spacer layer 150 may cover the first and second regions R1 and R2. The second spacer layer 150 may cover sidewalls and top surfaces of the preliminary mask patterns 122 on the first and second regions R1 and R2.

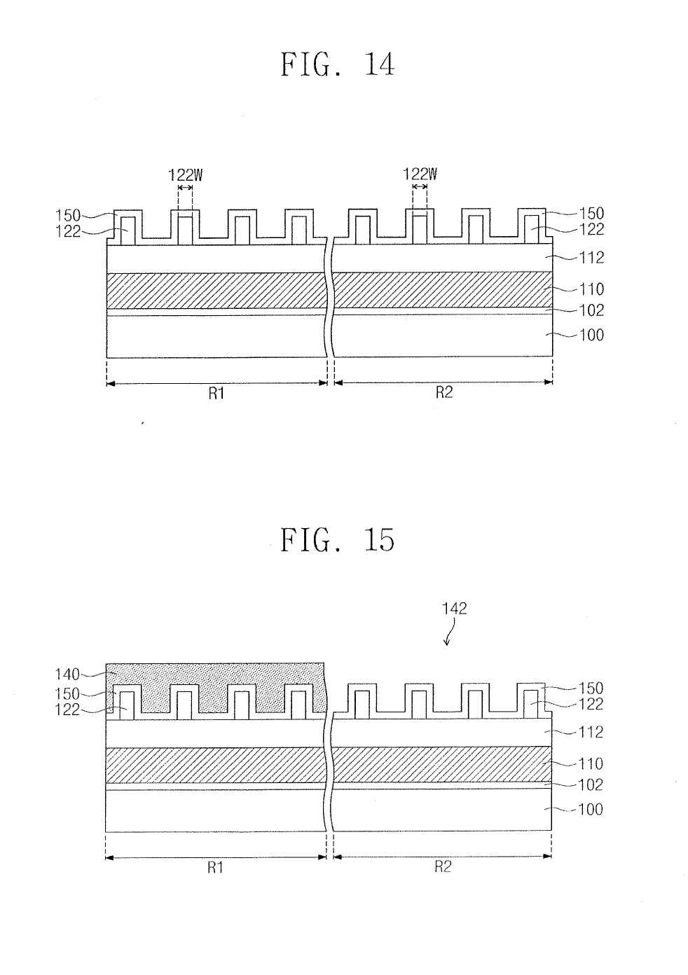

Referring to FIGS. 7A and 15, the mask pattern 140 may be formed on the substrate 100 (S500). The mask pattern 140 may have the opening 142 that exposes one of the first and second regions R and R2. According to the current embodiment, as shown in FIG. 15, the mask pattern 140 may have the opening 142 through which the second region R2 is exposed. The mask pattern 140 may cover the second spacer layer 150 on the first region R1. The opening 142 may expose the second spacer layer 150 on the second region R2.

The mask pattern 140 may be formed by using the mask layout ML that is designed by a design method of a semiconductor integrated circuit layout according to exemplary embodiments. The detailed formation of the mask pattern 140 may be substantially the same as that discussed with reference to FIG. 7B. According to the current embodiment, the mask layout ML may define a planar shape of the mask pattern 140 covering the first region R1 of the substrate 100. For example, the mask pattern 140 may be formed to have the opening 142 exposing the second region R2 and also to have a planar shape defined by the mask layout ML.

Referring to FIG. 16, the second spacer layer 150 exposed through the opening 142 may be removed from the second region R2. The removal of the second spacer layer 150 may include performing an etch process having an etch selectivity to the mask pattern 140, the preliminary mask patterns 122, and the gate capping layer 112. As the second spacer layer 150 is removed from the second region R2, sidewalls and top surfaces of the preliminary mask patterns 122 on the second region R2 may be exposed.

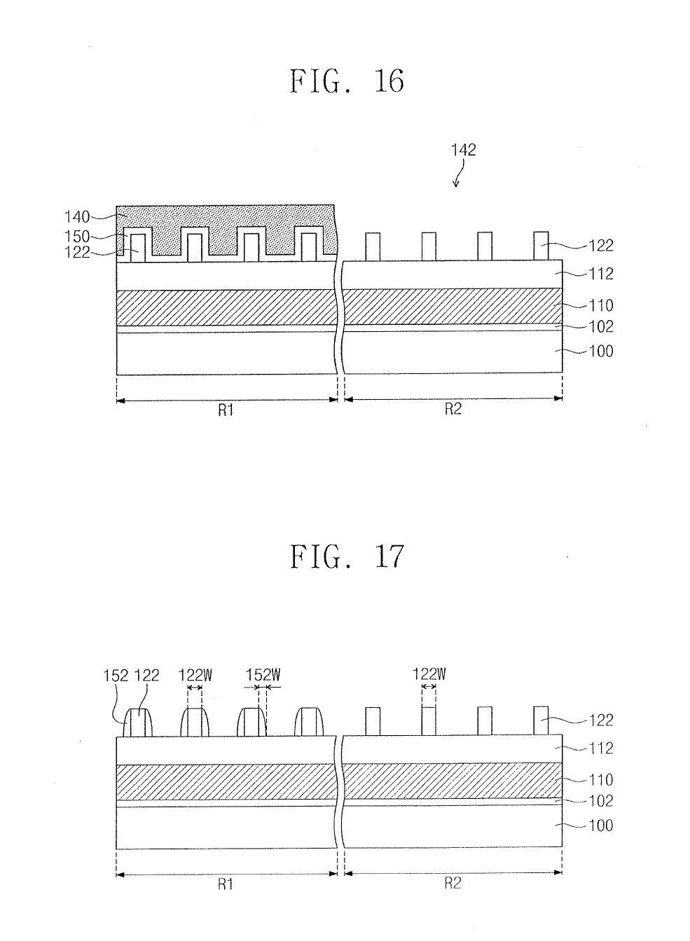

Referring to FIGS. 7A and 17, the second spacer patterns 152 may be formed on the sidewalls of the preliminary mask patterns 122 on the first region R1 (S600). The formation of the second spacer patterns 152 may include removing the mask pattern 140 and performing an anisotropic etch process on the second spacer layer 150 on the first region R1. The mask pattern 140 may be removed by performing, e.g., an ashing and/or strip process. The etch process may expose the top surfaces of the preliminary mask patterns 122 on the first region R1 and the top surface of the gate capping layer 112 between the preliminary mask patterns 122 on the first region R1. The etch process may have an etch selectivity to the preliminary mask patterns 122 and the gate capping layer 112. The second spacer patterns 152 may have the same maximum width 152W with each other. The mask pattern 140 may cause or facilitate the second spacer patterns 152 to locally or selectively form on the first region R1. Thereafter, as discussed with reference to FIGS. 7A, 12, and 13, the preliminary mask patterns 122 and the second spacer patterns 152 may be used to form the first gate electrode patterns GE1 on the first region R1 and the second gate electrode patterns GE2 on the second region R2 (S700). Each of the first gate electrode patterns GE1 may have the first gate length GL, and each of the second gate electrode patterns GE2 may have the second gate length GL2. As the first gate electrode patterns GE1 are formed to have different gate lengths from those of the second gate electrode patterns GE2, the first region R1 may be provided thereon with transistors whose operating characteristics are different from those of transistors provided on the second region R2.

According to an embodiment, in a step for designing a semiconductor integrated circuit layout, first and second gate patterns may be designed to have different gate lengths from each other without being provided with a biasing marker. The first and second gate patterns and a Boolean equation may be used to easily design a mask layout selectively overlapping the first gate pattern. In a method of fabricating a semiconductor device, preliminary mask patterns having the same width with each other may be formed on a substrate including first and second regions. Second spacer patterns may be formed on sidewalls of the preliminary patterns on the first region by using a mask pattern having an opening that exposes one of the first and second regions. The mask pattern may be used to locally form the second spacer patterns on the first region. The mask pattern may be formed by transferring the mask layout onto the substrate. The preliminary mask patterns and the second spacer patterns may be used to form first and second gate electrodes GE1 and GE2 having different gate lengths from each other on the first and second regions, respectively.

As a result, the first and second gate electrodes having a fine pitch may be easily formed to have different gate lengths from each other.

By way of summation and review, in the layout design, a design rule may determine basic operating characteristics of devices. For example, a gate length of a transistor may be primarily defined by the design rule. In case that a desired device property is not obtained through the gate length determined by the design rule, various device characteristics may be acquired by minutely adjusting the gate length at the step of designing layout or manufacturing process for semiconductor devices.

The embodiments may provide a design method of a semiconductor integrated circuit layout and a method of fabricating a semiconductor device in which gate patterns are easily formed to have fine pitch and different gate lengths.

As is traditional in the field, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope herein. Further, the blocks, units and/or modules of the embodiments may be physically combined into more complex blocks, units and/or modules without departing from the scope herein.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A design method of a semiconductor integrated circuit layout, the method comprising:
selecting a first cell layout including at least one first gate pattern;
selecting a second cell layout including at least one second gate pattern, the at least one second gate pattern having a gate length that is different from a gate length of the at least one first gate pattern;
producing a pattern layout including the first and second cell layouts; and
producing a mask layout selectively overlapping the first cell layout on the pattern layout.

2. The method as claimed in claim 1, wherein:
the first cell layout includes a plurality of first gate patterns that extend in a first direction and are arranged in a second direction crossing the first direction, and
the second cell layout includes a plurality of second gate patterns that extend in the first direction and are arranged in the second direction.

3. The method as claimed in claim 2, wherein:
each first gate pattern of the plurality of the first gate patterns has a first gate length, and
each second gate pattern of the plurality of the second gate patterns has a second gate length that is less than the first gate length.

4. The method as claimed in claim 3, wherein:
the plurality of first gate patterns are spaced apart from each other at a first distance along the second direction, and
the plurality of second gate patterns are spaced apart from each other at a second distance along the second direction, the second distance being different from the first distance.

5. The method as claimed in claim 4, wherein the first gate length, the second gate length, the first distance, and the second distance each have different values from one another.

6. The method as claimed in claim 2, wherein:
producing the pattern layout includes placing and routing the first and second cell layouts based on a preset design rule, in plan view,
in the pattern layout, the plurality of first gate patterns are disposed to extend in the first direction and arranged in the second direction, and the plurality of second gate patterns are disposed to extend in a same direction as the extending direction of the plurality of first gate patterns and arranged in a same direction as the arrangement direction of the plurality of first gate patterns.

7. The method as claimed in claim 6, wherein the mask layout overlaps the plurality of first gate patterns and extends in the second direction to overlap regions between the plurality of first gate patterns.

8. The method as claimed in claim 7, wherein:
each first gate pattern of the plurality of first gate patterns has a width in the first direction, and the mask layout has a width in the first direction, and
the width of the mask layout is the same as the width of each first gate pattern of the plurality of first gate patterns.

9. The method as claimed in claim 7, wherein the mask layout is produced by using a Boolean equation.

10. The method as claimed in claim 9, wherein producing the mask layout includes:
providing, on the pattern layout, imaginary patterns each overlapping a corresponding one of the plurality of the first gate patterns;
extending each of the imaginary patterns in the second direction; and
defining the mask layout by merging overlapping ones of the extended imaginary patterns,
wherein extending and merging the imaginary patterns are performed by using the Boolean equation.

11.-30. (canceled)

31. A design method of a semiconductor integrated circuit layout, the method comprising:
selecting a first cell layout from a cell library including various cell layouts for forming the semiconductor integrated circuit, the first cell layout including at least one first gate pattern;
selecting a second cell layout from the cell library, the second cell layout including at least one second gate pattern, the least one second gate pattern having a gate length that is different from a gate length of the at least one first gate pattern;
producing a pattern layout by placing and routing the first and second cell layouts based on a preset design rule; and
producing a mask layout selectively overlapping the first cell layout on the pattern layout.

32. The method as claimed in claim 31, wherein the pattern layout includes a plurality of the first cell layouts and a plurality of the second cell layouts that are arranged along a first direction and a second direction crossing the first direction, and
wherein the mask layout includes a plurality of mask layouts, and each of the plurality of mask layouts selectively overlaps a corresponding one of the plurality of the first cell layouts.

33. The method as claimed in claim 31, wherein:
the first cell layout includes a plurality of first gate patterns that extend in a first direction and are arranged in a second direction crossing the first direction, and
the second cell layout includes a plurality of second gate patterns that extend in the first direction and are arranged in the second direction.

34. The method as claimed in claim 33, wherein
each first gate pattern of the plurality of the first gate patterns has a first gate length,
each second gate pattern of the plurality of the second gate patterns has a second gate length that is different from the first gate length,
the plurality of first gate patterns are spaced apart from each other at a first distance along the second direction, and
the plurality of second gate patterns are spaced apart from each other at a second distance along the second direction, the second distance being different from the first distance.

35. The method as claimed in claim 34, wherein the first gate length, the second gate length, the first distance, and the second distance each have different values from one another.

36. The method as claimed in claim 33, wherein the mask layout overlaps the plurality of first gate patterns and extends in the second direction to overlap regions between the plurality of first gate patterns.

37. The method as claimed in claim 36, wherein the mask layout overlaps neither the plurality of second gate patterns nor regions between the plurality of second gate patterns.

38. The method as claimed in claim 36, wherein
each first gate pattern of the plurality of first gate patterns has a width in the first direction, and the mask layout has a width in the first direction, and
the width of the mask layout is the same as the width of each first gate pattern of the plurality of first gate patterns.

39. The method as claimed in claim 33, wherein producing the mask layout includes:
providing, on the pattern layout, imaginary patterns each overlapping a corresponding one of the plurality of the first gate patterns;
extending each of the imaginary patterns in the second direction; and
defining the mask layout by merging overlapping ones of the extended imaginary patterns.

40. The method as claimed in claim 31, wherein the mask layout do not overlap the second cell layout.
